(19) United States
(12) Patent Application Publication
(10) Pub. No.: US 2017/0040205 A1
(43) Pub. Date: Feb. 9, 2017

(54) HIGH-HARDNESS-MATERIAL-POWDER INFUSED ELASTOMER FOR HIGH FRICTION AND COMPLIANCE FOR SILICON WAFER TRANSFER

(71) Applicant: Lam Research Corporation, Fremont, CA (US)

(72) Inventors: Jacob L. Hiester, Beaverton, OR (US); Richard M. Blank, San Jose, CA (US); Tyson L. Ringold, Mountain View, CA (US); Peter J. Woytowitz, Los Altos, CA (US); Mohsen S. Salek, Saratoga, CA (US)

(21) Appl. No.: 15/219,663

(22) Filed: Jul. 26, 2016

Related U.S. Application Data
(60) Provisional application No. 62/201,515, filed on Aug. 5, 2015.

(51) Int. Cl. H01L 21/687; B25J 15/00; H01L 21/67

(52) U.S. Cl. CPC H01L 21/68707; H01L 21/67201; B25J 15/0014

(57) ABSTRACT

Disclosed herein, a contact pad for use on a robot arm in transfer chamber in a wafer processing tool is provided, comprising an elastomer body and a high hardness powder doping a surface of the elastomer body.

### CROSS REFERENCE TO RELATED APPLICATION

This application claims the benefit of priority of U.S. Provisional Application No. 62/201,515, filed Aug. 5, 2015, which is incorporated herein by reference for all purposes.

### BACKGROUND

This disclosure relates to the processing of wafers in a processing system. More specifically the disclosure relates to a transfer device used in a wafer processing system.

In semiconductor processing, substrates are moved into and around a processing system. Robotic devices within the processing system are used to move the substrates.

### SUMMARY

Disclosed herein are various embodiments, including a contact pad for use in a wafer processing tool, comprising an elastomer body and a high hardness powder doping a surface of the elastomer body.

In another manifestation, a processing tool, for processing a substrate is provided. A load lock chamber is provided. A transport module chamber is connected to the load lock chamber, wherein the transport module chamber comprises an end effector and at least three contact pads connected to the end effector. Each contact pad comprises an elastomer body and a high hardness powder doping a surface of the elastomer body. At least one processing chamber is connected to the transport module chamber.

These and other features of the present inventions will be described in more detail below in the detailed description and in conjunction with the following figures.

### BRIEF DESCRIPTION OF THE DRAWINGS

The disclosed embodiments are illustrated by way of example, and not by way of limitation, in the figures of the accompanying drawings and in which like reference numerals refer to similar elements and in which:

FIG. 1 is a top schematic view of a processing tool, which uses an embodiment.

FIG. 2 is a schematic view of an end effector of a robot arm that is used in one embodiment.

FIG. 3 shows an embodiment of a contact pad.

FIG. 4 is a schematic view of an end effector used in another embodiment.

FIG. 5 is a cross-sectional perspective view of another contact pad mounted in a circular indentation of an end effector.

FIG. 6 is an enlarged schematic cross-sectional view of an upper surface of a contact pad doped with a high hardness powder engaged with a bottom of a wafer.

### DETAILED DESCRIPTION

Inventions will now be described in detail with reference to a few of the embodiments thereof as illustrated in the accompanying drawings. In the following description, specific details are set forth in order to provide a thorough understanding of the present invention. However, the present invention may be practiced without some or all of these specific details, and the disclosure encompasses modifications which may be made in accordance with the knowledge generally available within this field of technology. Well-known process steps and/or structures have not been described in detail in order to not unnecessarily obscure the present disclosure.

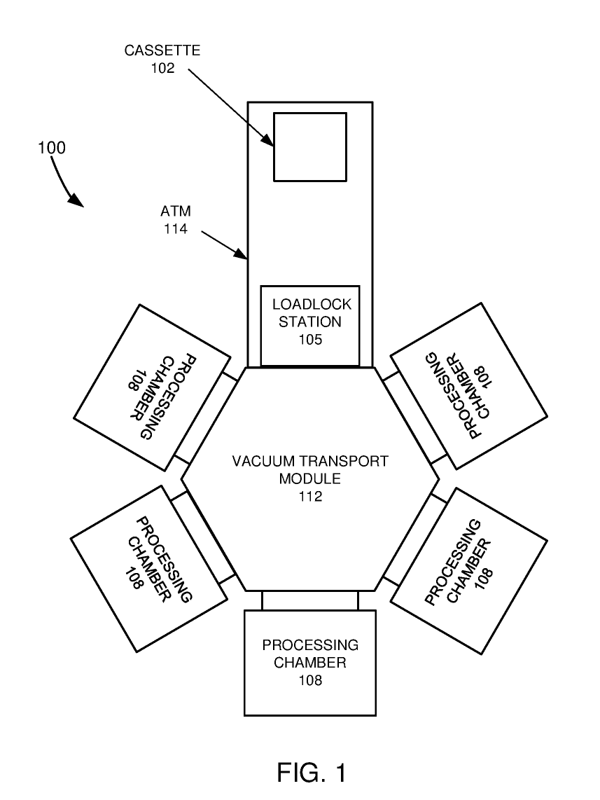

FIG. 1 is a top schematic view of a processing tool 100, which uses an embodiment. A cassette 102 houses the unprocessed wafers before they are processed and then hold the treated wafers once all processing is complete in the processing tool 100. The cassette 102 can hold many wafers, often as many as 25. An atmosphere transport module (ATM) 114 is used to transport wafers to and from the cassette 102. A load lock station 105 represents at least one device that operates to transfer the wafer back and forth between the atmosphere of the ATM 114 and the vacuum of a vacuum transport module (VTM) 112. The VTM 112 is part of the processing tool and connects to a plurality of processing chambers 108. There may be different types of processing chambers 108. For example, there may be different processing chambers 108 for each of the following: applying an etch mask, etching, stripping an etch mask, depositing a dielectric film, or depositing a metallic film. Alternatively, there may be two or more of the same type of processing chamber 108, in order to help increase throughput. A robotic system within the vacuum transport module 112 uses an end effector to move a wafer between the load lock station 105 and the processing chambers 108. The ATM 114 uses a robotic system to transfer wafers between the cassette 102 and the load lock station 105. The processing tool 100 may use an end effector to transfer the wafer from atmosphere to a vacuum environment. A processing chamber may cause the wafer to be heated to a temperature of 400° C. (or higher), so that the end effector may handle wafers that are at temperatures up to 400° C. (or higher).

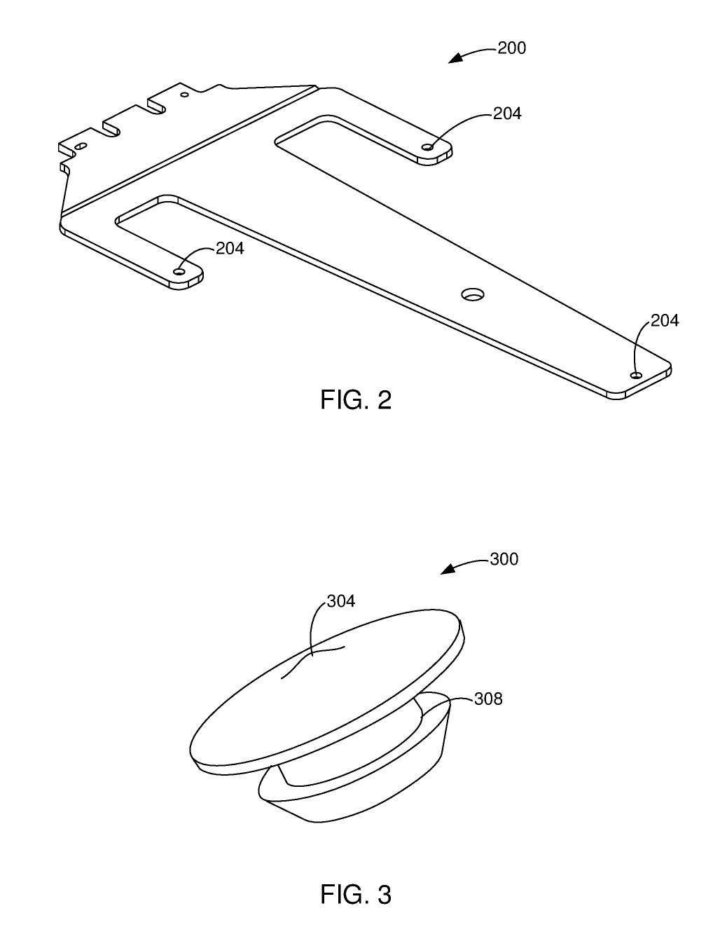

FIG. 2 is a schematic view of an end effector 200 of a robot arm that is used in one embodiment. The end effector 200 has three contact point apertures 204. FIG. 3 shows an embodiment of a contact pad 300 that mounts to the contact point apertures 204. The contact pad 300 is made of an elastomer body doped with a high hardness powder. The contact pad 300 comprises a contact surface 304 and an attachment stem 308. In this embodiment, the contact surface 304 is slightly pointed, so that most of the engagement between the contact surface 304 and a wafer is near the tip of the pointed contact surface 304. In this embodiment, the attachment stem 308 has a frustoconical end, as shown, for pushing through the contact point aperture in the end effector and holding the contact pad in the contact point aperture. The end effector is moved under a wafer and then raised so that three mounted contact pads 300 contact the wafer.

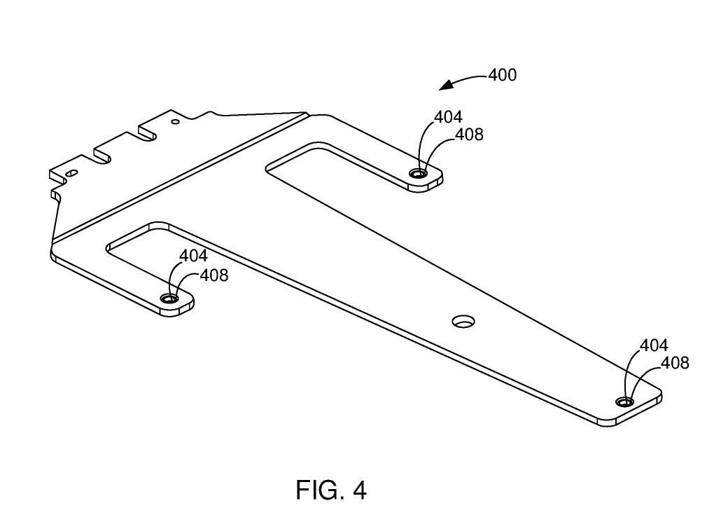

FIG. 4 is a schematic view of an end effector 400 used in another embodiment before contact pads are mounted. At the contact points are contact point apertures 404. Surrounding the contact point apertures 404 are circular indentations 408.

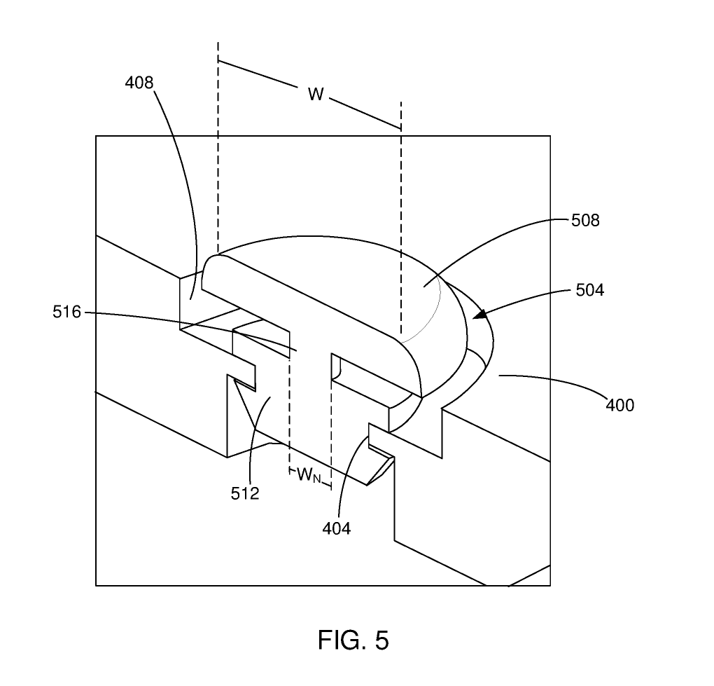

FIG. 5 is a cross-sectional perspective view of a contact pad 504 mounted in a circular indentation 408 of the end effector 400. The contact pad 504 comprises a contact surface 508, an attachment stem 512, and a neck 516 connected between the contact surface 508 and the attachment stem 512. The attachment stem 512 passes through the contact point aperture 404. In this embodiment the contact surface 508 has a flat surface, which engages the wafer for a greater contact with the wafer. A more flexible neck allows the contact surface 508 to be angled to better engage the wafer. An attaching stem attaches the contact pad to the end effector. Preferably, the contact surface 508 has a width “W” and length or diameter in the range of 1/16″ to 1″. More preferably, the contact surface 508 has a width and length or diameter in the range of ⅛″ to ¼″. The neck 516 has a width “W_{N}”. Preferably, the width of the neck 516 is less than half of the width of the contact surface 508. More preferably, the width of the neck 516 is less than one fourth of the width of the contact surface 508. The height of the neck 516 may be minimal, since the contact surface 508 of the contact pad 504 will only need to have slight deflections. However, to accommodate the deflections, the neck should have a width that is less than half the width of the contact surface. Preferably, the top of the contact 508 surface of the contact pad 504 extends no more than 1 mm above a top surface of the end effector 400. By placing the contact pad 504 in a circular indentation, the contact pad 504 may have a neck greater than 1 mm, while maintaining the upper surface of the contact surface 508 to be less than 1 mm above the top surface of the end effector 400. Keeping the upper surface of the contact surface 508 within 1 mm above the top surface of the end effector 400 provides required clearance for the end effector 400.

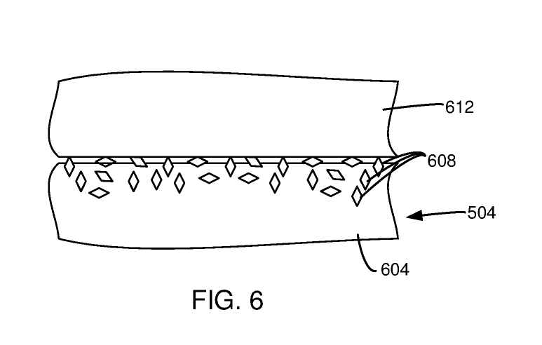

FIG. 6 is an enlarged schematic cross-sectional view of an upper surface of the contact pad 504 comprising an elastomer body 604 doped with a high hardness powder 608 engaged with a bottom of a wafer 612. The high hardness powder 608 provides contact with the bottom of the wafer 612, which increases the force of friction between the wafer 612 and the contact pad 504. The high hardness powder 608 is more densely packed, which increases the contact area, but is not shown, to simplify the drawing.

In one embodiment, the contact pad is formed out of an elastomer. Then before, during, or after curing the elastomer, the high hardness powder is applied to dope the upper surface of the contact pad. In this example, some of the high hardness powder projects above the upper surface of the contact pad. In addition, some of the high hardness powder is completely under the upper surface of the contact pad. In other embodiments, the high hardness powder may not project above the upper surface of the contact pad. Preferably, the high hardness powder is added during curing. In other embodiments, the high hardness powder may be added before the elastomer is shaped.

Some of the elastomers may be unsaturated rubbers, saturated rubbers, specifically perfluoroelastomers, or thermoplastics. Preferably, the elastomer is a perfluorelastomer, which meets the requirements of plasma processing, such as functioning within the operating temperatures of such chambers with minimal out gassing in a vacuum environment. Some of the high hardness powders may be ceramic powder of oxides, nitrides, or carbides, which have a higher hardness than the silicon wafer. More specific examples of the high hardness powder may be alumina (aluminum-oxide), zirconia (zirconium-oxide), silicon-carbide, boron-carbide, tungsten-carbide, aluminum-nitride, silicon-nitride, or diamond.

It is believed that the contact pads with high hardness powder increase the friction (wafer holding) force to allow higher robotic acceleration without slipping, which results in higher throughput.

The current limitation for robot throughput in wafers per hour (WPH) is measured by one complete sequence of operations for wafer transfer in a system which is running steady-state. In this particular application, a ceramic robot end effecter is used on a silicon wafer when handling hot wafers. This is because ceramic is clean and can handle running at high temperatures. The friction force limitation in this application, and associated acceleration limitation, is 0.1 g. If an elastomeric material is able to be used when handling hot wafers (>350 C) the acceleration can be increased (>1.0 g with other elastomers) and robot throughput can be improved. In the case of a robot limited system, a robot throughput improvement could translate directly to a system throughput increase as well.

Most robotics devices in semiconductor capital equipment tools which process under vacuum will use friction as the holding mechanism for wafer transfer. Higher friction is typically desired in this application which will allow for faster transfer speeds and higher system throughput (wafers transferred or processed per hour). Typically elastomeric materials are used for wafer contact pads which can allow for higher friction than other materials. Such elastomers alone are not able to handle the high temperatures, because they may lose their shape or may produce an out gas at temperatures of about 400° C. If a very high hardness powder (silicon, silicon carbide, diamond particles) is added to an elastomer as part of the material manufacturing, it can create advantages for either further increasing the friction and/or allow use at high temperatures while still maintaining a compliant shape for contact to the surface of wafer. Such high hardness powder would act like grit on sand paper. The addition of the high hardness powder causes the elastomer to be less susceptible to the higher heat and may increase the friction with the wafer. If the wafers are at a high temperature, the higher hardness powder provides additional isolation between the hot wafer and the elastomer. In addition, a high temperature may soften the elastomer, which would normally increase stiction. The high hardness powder will help prevent such an increase in stiction when the elastomer softens. Additional benefits could include lower release force (stiction) when disengaging contact between pad and wafer. Because the high hardness powder has a hardness higher than the silicon wafer, the powder will not be damaged by contact with the silicon wafer.

This embodiment provides an improvement over hard contact points, which may be made of a solid hard material without an elastomer. Such solid hard material without an elastomer may have reduced friction, which would decrease wafer throughput.

While inventions have been described in terms of several preferred embodiments, there are alterations, permutations, and various substitute equivalents, which fall within the scope of this invention. There are many alternative ways of implementing the methods and apparatuses disclosed herein. It is therefore intended that the following appended claims be interpreted as including all such alterations, permutations, and various substitute equivalents as fall within the true spirit and scope of the present invention.

What is claimed is:

1. A contact pad for use on a robot arm in a wafer processing tool, comprising:
an elastomer body; and
a high hardness powder doping a surface of the elastomer body.

2. The contact pad, as recited in claim 1, wherein the elastomer body comprises:
a contact surface; and
an attaching stem for attaching the contact pad to an end effector.

3. The contact pad, as recited in claim 2, wherein the elastomer body further comprises a neck connected between the contact surface and the attaching stem, wherein the neck has a width that is less than half a width of the contact surface.

4. The contact pad, as recited in claim 3, wherein the high hardness powder comprises at least one of alumina (aluminum-oxide), zirconia (zirconium-oxide), silicon-carbide, boron-carbide, tungsten-carbide, aluminum-nitride, silicon-nitride, or diamond.

5. The contact pad, as recited in claim 4, wherein the elastomer body comprises at least one of unsaturated rubbers, saturated rubbers, or thermoplastics.

6. The contact pad, as recited in claim 4, wherein the elastomer body comprises perfluoroelastomers.

7. The contact pad, as recited in claim 1, wherein the high hardness powder comprises at least one of alumina (aluminum-oxide), zirconia (zirconium-oxide), silicon-carbide, boron-carbide, tungsten-carbide, aluminum-nitride, silicon-nitride, or diamond.

8. The contact pad, as recited in claim 7, wherein the elastomer body comprises at least one of unsaturated rubbers, saturated rubbers, or thermoplastics.

9. The contact pad, as recited in claim 7, wherein the elastomer body comprises perfluoroelastomers.

10. A processing tool, for processing a substrate, comprising:
a load lock chamber;
a transport module chamber connected to the load lock chamber, wherein the transport module chamber comprises:
an end effector; and
at least three contact pads connected to the end effector, wherein each contact pad comprises:
an elastomer body; and
a high hardness powder doping a surface of the elastomer body; and
at least one processing chamber connected to the transport module chamber.

11. The contact pad, as recited in claim 10, wherein each elastomer body comprises:
a contact surface; and
an attaching stem for attaching the contact pad to an end effector.

12. The contact pad, as recited in claim 11, wherein each elastomer body further comprises a neck connected between the contact surface and the attaching stem, wherein the neck has a width that is less than half a width of the contact surface.

13. The contact pad, as recited in claim 12, wherein the high hardness powder comprises at least one of alumina (aluminum-oxide), zirconia (zirconium-oxide), silicon-carbide, boron-carbide, tungsten-carbide, aluminum-nitride, silicon-nitride, or diamond.

14. The contact pad, as recited in claim 13, wherein the elastomer body comprises at least one of unsaturated rubbers, saturated rubbers, or thermoplastics.

15. The contact pad, as recited in claim 13, wherein the elastomer body comprises perfluoroelastomers.

16. The contact pad, as recited in claim 10, wherein the high hardness powder comprises at least one of alumina (aluminum-oxide), zirconia (zirconium-oxide), silicon-carbide, boron-carbide, tungsten-carbide, aluminum-nitride, silicon-nitride, or diamond.

17. The contact pad, as recited in claim 16, wherein the elastomer body comprises at least one of unsaturated rubbers, saturated rubbers, or thermoplastics.

18. The contact pad, as recited in claim 16, wherein the elastomer body comprises perfluoroelastomers.
